(19) United States
(12) Patent Application Publication
(10) Pub. No.: US 2003/0224114 A1
(43) Pub. Date: Dec. 4, 2003

(54) Method for making an improved aerogel catalyst for making single-wall carbon nanotubes by chemical vapor deposition

(76) Inventor: Yuemei Yang, Houston, TX (US)

Correspondence Address: Kenneth D. Goodman, Williams, Morgan & Amerson, P.C., Suite 1100, 10333 Richmond, Houston, TX, 77042, US

(21) Appl. No.: 10/375,916

(22) Filed: Feb. 27, 2003

Related U.S. Application Data
(60) Provisional application No. 60/359,920, filed on Feb. 27, 2002.

(51) Int. Cl. C23C 16/00; B05D 3/02

(52) U.S. Cl. 427/376.1; 427/249.1

(57) ABSTRACT

A catalyst suitable for making carbon nanotubes is formed by depositing a transition-metal compound on an aerogel support to form a supported catalyst, calcining the supported catalyst, and activating the catalyst by reducing the transition-metal compound on the support. The transition-metal compound can comprise, for example, at least one element from Group VIII-B or Group VI-B, such as iron, cobalt or a combination thereof. The aerogel can comprise, for example, a material selected from the group consisting of alumina, magnesia, alumina/silica, silica and combinations thereof.

This patent application claims priority from U.S. provisional application 60/359,920, filed on Feb. 27, 2002, which is incorporated herein in its entirety.

### BACKGROUND OF THE INVENTION

Chemical vapor deposition processes for producing single-wall carbon nanotubes typically involve forming single-wall carbon nanotubes with a catalyst comprising transition metal particles supported on an oxide, such as silica, magnesia or alumina. “High Yield Vapor Phase Deposition Method for Large Scale Single Walled Carbon Nanotube Preparation” by Jie Liu, International Pat. Publ. WO 01/49599 A2, published Jul. 12, 2001, (“WO 01/49599 A2”) and incorporated herein by reference in its entirety, discloses an improved catalyst for making single-wall carbon nanotubes by chemical vapor deposition. In this reference an aerogel is used as the catalyst support. The high surface area of the support provides more area to serve as sites for individual nanometer-sized metal catalyst particles.

Aerogels of alumina or alumina/silica may be made by standard methods. (See D. J. Suh and J. T. Park, Chemistry of Materials 9, 1903-5). Aerogel preparation typically involves formation of a gel, such as by the partial hydrolysis of aluminum sec-butoxide, and supercritical drying. After drying, the aerogel is calcined in an oxygen-containing atmosphere to produce an aerogel with a specific surface area of up to 700 m²/gram. In WO 01/49599 A2, transition-metal-containing reagents (such as Fe₂(SO₄)₃·4H₂O and MoO₂(acac)₂) are used in the gel formation, resulting in formation of an aerogel that contains transition metals. With appropriate heat treatment, the transition metals aggregate on the aerogel support into catalytic particles of a size appropriate to catalyze growth of single-wall carbon nanotubes. This gel-formation procedure is tedious and involves expensive reagents. For commercial production of single-wall carbon nanotubes, an improved, lower cost supported catalyst for forming single-wall carbon nanotubes using chemical vapor deposition processes is sought.

### SUMMARY OF THE INVENTION

The present invention provides an improved method for forming a supported catalyst for growing single-wall carbon nanotubes in chemical vapor deposition processes. The improved catalyst comprises, in certain embodiments of the invention, transition metal clusters on a high-surface-area aerogel support. In one embodiment of the invention, the method comprises making an aerogel support, impregnating the support with a transition metal-containing compound either in a gaseous or liquid phase, drying (if necessary) and calcining. The calcined catalyst is provided to a reactor, and activated, such as by hydrogen reduction. Catalyst activation can, in one embodiment, take place upon introduction of an appropriate feed gas into the reactor. A carbon-containing feedstock comprising CO, a hydrocarbon gas, a hydrocarbon vapor, or a mixture thereof is provided to the reactor wherein the pressure and temperature are adjusted to conditions conducive for single-wall carbon nanotube growth. After sufficient reaction time, the single-wall carbon nanotubes, catalyst and support are recovered from the reactor and subjected to a chemical process, such as an acid treatment, to remove the catalyst and support.

Certain embodiments of the invention have the advantage that commercially-available aerogel compositions may be used and the reagents required for the impregnation process are substantially less expensive than those used in WO 01/49599 A2, in which the metals are incorporated in the formation of the gel.

Another embodiment of the present invention is an aerogel-supported catalyst composition for single-wall carbon nanotube growth where the transition metal on the support comprises iron and cobalt. This combination is beneficial compared to other catalyst compositions that use molybdenum in that the iron-cobalt combination is more easily removed by inexpensive acid treatment.

### DETAILED DESCRIPTION OF SPECIFIC EMBODIMENTS

One embodiment of the invention is a method for forming a catalyst that is suitable for making carbon nanotubes. The method comprises depositing a transition-metal compound on an aerogel support to form a supported catalyst, calcining the supported catalyst, and activating the catalyst by reducing the transition-metal compound on the support. In certain specific embodiments, the transition-metal compound comprises at least one element from Group VIII-B or Group VI-B of the periodic table, such as iron, cobalt or a combination thereof. In one embodiment, the aerogel comprises a material selected from the group consisting of alumina, magnesia, alumina/silica, silica and combinations thereof.

Another embodiment of the invention is a catalyst for growing single-wall carbon nanotubes, the catalyst being produced by the above-described method.

Still another embodiment of the invention is a method for growing single wall carbon nanotubes. This method comprises providing a catalyst comprising a transition-metal catalyst on an aerogel support to a reactor, providing a gaseous carbon-containing feedstock to the reactor at a temperature and pressure sufficient to grow single-wall carbon nanotubes on the catalyst, and removing the catalyst to the recover single-wall carbon nanotubes. In a particular embodiment, the carbon-containing feedstock comprises at least one of carbon monoxide, hydrocarbons, alcohols, and combinations thereof. One specific example of a suitable carbon-containing feedstock is ethanol.

### EXAMPLE

5.8 g aluminum sec-butoxide was added in 50 ml EtOH. The mixture was refluxed and stirred until a clear solution was formed. 10 ml NH₄OH solution (conc. NH₄OH:EtOH=1:5) was slowly added to the solution and a thick sol-gel gradually formed. The sol-gel was aged at room temperature for 48 hours. EtOH in sol-gel was exchanged with liquid CO₂ at 2-5° C. for 2.5 hours in a high-pressure vessel. The high-pressure vessel containing the gel was raised above the CO₂ supercritical point. The vessel was depressurized slowly. Low-density Al₂O₃ aerogel was retrieved from the vessel and calcined in air at 500° C. for 30 min. 0.036 g Fe(CH₃COO)₂ and 0.0470 g of Co(CH₃COO)₂·4H₂O was dissolved in 20 ml EtOH. 0.5 g of the prepared Al₂O₃ aerogel was added to the solution. The ethanol was removed by vacuum drying and calcined in air at 500° C. for 1 hour. A pink catalyst was obtained.

Using this catalyst, carbon nanotubes were grown in a fixed fluidized reactor. 0.18 g catalyst was used. The reactor temperature was raised to 800° C. under Ar flow (120 sccm). H₂ gas (150 sccm) was introduced to the Ar flow, and then the Ar was switched off for 10 min. After catalyst reduction, the H₂ gas was switched off and the Ar gas was switched on again, but this time the Ar gas passed through a bubbler filled with EtOH, held at 21° C. The reaction to make single-wall carbon nanotubes was conducted at 800° C. for 30 min. The reactor was cooled to room temperature under Ar flow. Thermogravimetric analysis measurement indicated a carbon weight gain of 12% with respect to catalyst weight. High-resolution TEM images were taken on the retrieved material. Single-wall nanotubes bundles and large diameter single-walled nanotubes (greater than about 3 nm) were observed.

The preceding description of specific embodiments of the present invention is not intended to be a complete list of every possible embodiment of the invention. Persons skilled in this field will recognize that modifications can be made to the specific embodiments described here that would be within the scope of the following claims.

What is claimed is:

1. A method for forming a catalyst for making carbon nanotubes, comprising:
depositing a transition-metal compound on an aerogel support to form a supported catalyst;
calcining the supported catalyst; and
activating the catalyst by reducing the transition-metal compound on the support.

2. The method of claim 1 wherein the transition-metal compound comprises at least one element from Group VIII-B or Group VI-B of the periodic table.

3. The method of claim 1 wherein the transition-metal compound comprises an element selected from the group consisting of iron, cobalt and combinations thereof.

4. The method of claim 1 wherein the aerogel comprises a material selected from the group consisting of alumina, magnesia, alumina/silica, silica and combinations thereof.

5. A catalyst for growing single-wall carbon nanotubes, made by the process comprising:
depositing a transition-metal compound on an aerogel support to form a supported catalyst;
calcining the supported catalyst; and
activating the catalyst by reducing the transition-metal compound on the support.

6. The catalyst of claim 5 wherein the transition-metal compound comprises at least one element from Group VIII-B or Group VI-B of the periodic table.

7. The catalyst of claim 5 wherein the transition-metal compound comprises an element selected from the group consisting of iron, cobalt and combinations thereof.

8. The catalyst of claim 5 wherein the aerogel comprises a material selected from the group consisting of alumina, magnesia, alumina/silica, silica and combinations thereof.

9. A method for growing single wall carbon nanotubes comprising:
providing a catalyst comprising a transition-metal catalyst on an aerogel support to a reactor;
providing a gaseous carbon-containing feedstock to the reactor at a temperature and pressure sufficient to grow single-wall carbon nanotubes on the catalyst; and
removing the catalyst to the recover single-wall carbon nanotubes.

10. The method of claim 9 wherein the transition-metal catalyst comprises at least one element from Group VIII-B or Group VI-B of the periodic table.

11. The method of claim 9 wherein the transition-metal catalyst comprises an element selected from the group consisting of iron, cobalt and combinations thereof.

12. The method of claim 9 wherein the aerogel comprises a material selected from the group consisting of alumina, magnesia, alumina/silica, silica and combinations thereof.

13. The method of claim 9 wherein the carbon-containing feedstock comprises at least one of carbon monoxide, hydrocarbons, alcohols, and combinations thereof.

14. The method of claim 13 wherein the carbon-containing feedstock comprises ethanol.
